(19) United States
(12) Patent Application Publication
(10) Pub. No.: US 2011/0279143 A1
(43) Pub. Date: Nov. 17, 2011

(54) SEMICONDUCTOR WAFER TESTING APPARATUS

(76) Inventors: Tadanobu Toba, Yokohama (JP); Katsunori Hirano, Yokohama (JP); Norio Sato, Hitachioota (JP); Masahiro Ohashi, Hitachinaka (JP)

(21) Appl. No.: 13/133,970

(22) PCT Filed: Sep. 18, 2009
(86) PCT No.: PCT/JP2009/004722

§ 371 Date: Jul. 26, 2011

(30) Foreign Application Priority Data
Dec. 12, 2008 (JP) 2008-317105

(51) Int. Cl. G01R 31/26

(52) U.S. Cl. 324/762.05

(57) ABSTRACT

Disclosed is a semiconductor wafer testing apparatus that resolves the following problems which arise when semiconductor wafers become larger: (1) complexity of stage acceleration/deceleration control; (2) throughput reduction; and (3) increased vibration of the stage support platform during the stage inversion operation (deterioration in resolution). In the semiconductor wafer testing apparatus for resolving these problems, a wafer is rotated, an electro beam is irradiated onto the rotating wafer from a scanning electron microscope, and secondary electrons emitted from the wafer are detected. The detected secondary electrons are A/D converted by an image processing unit, realigned by an image data realignment unit, and then image-processed for display. As a result, image information of all dies of a wafer can be acquired without a large amount of movement of the stage in the X and the Y directions.

### TECHNICAL FIELD

The present invention relates to a testing apparatus using an electron beam or optical laser for testing of semiconductor devices, substrates, photomasks (exposure masks), etc., having minute patterns.

### BACKGROUND ART

With recent evolution of further microfabrication and denser integration of semiconductor integrated circuits, testing of patterns created on semiconductor wafers is performed at the end of every manufacturing process to detect early or in advance any abnormality and/or any fault involved in the manufacturing process of these semiconductor integrated circuits. Such defect testing method and apparatus are put into practice use. In the testing apparatus of this kind, testing is performed by acquiring image information with respect to a region to be tested by means of a Scanning Electron Microscope (hereinafter abbreviated to SEM) using an electron beam technology.

A Critical-Dimension SEM, hereinafter referred to as a CD-SEM, which is a SEM using the electron beam technology specialized for semiconductors, is used for dimensional control of process patterns in the production of semiconductor integrated circuits. The CD-SEM carries out observing process patterns and measuring their dimensions with high precision.

In the process management in terms of a yield rate and other parameters of semiconductor integrated circuits, a testing apparatus such as, for example, a DR-SEM (Defect Review SEM) is used to detect a defect in the patterns of elements in a chip by means of a SEM using the electron beam technology.

In apparatus using any of these scanning electron microscopes (SEMs), a region to be inspected on a semiconductor wafer is scanned by electron beam irradiation which takes place sequentially along a plurality of scan lines with a predetermined acceleration voltage, image information for the region to be inspected is acquired by detecting secondary electrons reflected from there, and testing of the region to be inspected is performed based on the acquired image information. However, along with increased diameter and further fineness of circuit patterns of recent semiconductor wafers, increasing the throughput of the apparatus is required. Especially, 450-mm wafers are expected to be developed in the time to come and there is a noticeable tendency toward increasing the wafer diameter. Due to this, the foregoing testing apparatus will encounter a problem that an X-Y stage for controlling a beam irradiation position needs to be enlarged, which, in turn, increases the weight of the apparatus and entails an additional cost. In order to increase the throughput, it is necessary that a region to be inspected is positioned in a beam irradiation position promptly and accurately, electron beam scanning control is implemented at a higher speed, and acquired image information is processed at a higher speed.

“Patent Document 1” describes a related art apparatus for wafer testing using a SEM for inspecting a wafer, while moving a stage in X and Y directions. “Patent Document 2” describes a technique in which a plurality of wafers are mounted on a stage and a defect is detected by rotating the stage and comparing the images of both wafers.

### RELATED ART DOCUMENTS

### Patent Documents

Patent Document 1: Japanese Published Unexamined Patent Application No. 2000-100362
Patent Document 2: Japanese Published Unexamined Patent Application No. 2001-291094

### DISCLOSURE OF THE INVENTION

### Problems to be Solved by the Invention

Because of the fact that the stage is made larger and heavier due to increased diameter of recent semiconductor wafers, the following problems are emerging: (1) complexity of control for accelerating and decelerating the stage; (2) a decrease in the throughput (an acceleration limit attributed to increased weight→a high torque limit of the motor); and (3) increased vibration of the stage support platform during the stage inversion operation (deterioration in resolution).

An object of the present invention is to make it feasible for apparatus for inspecting circuit patterns to avoid the stage from becoming larger due to increased diameter of wafers, to achieve downsizing, weight saving, and cost reduction, and achieve an improvement in the resolution for measurement and high throughput.

### Means of Solving the Problems

To solve the above-mentioned problems, the apparatus is configured with a stage that holds, rotates, and moves a wafer; means for irradiating the surface of the wafer that is rotated and moved by the stage by an electron beam; means for detecting secondary electrons that are generated from the wafer by the irradiating means; means for controlling scanning taking a rotation angle of the wafer into account; and means for acquiring image information based on the detected signals.

Likewise, the apparatus is configured with a stage that holds, rotates, and moves a wafer; means for irradiating the wafer, the surface which is rotated and moved by the stage, by an electron beam; means for detecting secondary electrons that are generated from the wafer by the irradiating means; means for controlling scanning with the electron beam; means for reordering acquired images taking a rotation angle of the wafer into account; and means for acquiring image information based on the detected signals.

### Effects of the Invention

According to the present invention, it is possible to reduce the size and the weight of the stage that holds a wafer and moves it to an irradiation region. It is also possible to improve the testing throughput by precluding a decrease in the throughput due to an acceleration limit (a high torque limit of the motor) attributed to increased weight of the stage of related art (what is called the X-Y stage) which makes movement in X-axis and Y-axis directions from an origin. The X-Y stage involves an inversion movement that is now eliminated by the present invention. Thus, the present invention makes it possible to reduce the vibration of the stage support platform and improve the resolution and precision of the testing.

### BRIEF DESCRIPTION OF THE DRAWINGS

FIG. 1 A structural diagram of a testing apparatus pertaining to an embodiment of the present invention.

FIG. 2 A diagram illustrating a stage control method and an electron beam scan method in a related-art testing apparatus.

FIG. 3 A diagram illustrating a stage control method and a scan control method in the testing apparatus pertaining to an embodiment of the present invention.

FIG. 4 A diagram illustrating a method for calculating coordinate correction values from a rotation angle.

FIG. 5 A diagram illustrating a method of scanning pixel by pixel in the testing apparatus pertaining to an embodiment of the present invention.

FIG. 6 A diagram illustrating a method of scanning in a fixed direction in the testing apparatus pertaining to an embodiment of the present invention.

FIG. 7 A diagram illustrating a method of scanning in a fixed direction, designed so that the scan covers only an area to be inspected, in the testing apparatus pertaining to an embodiment of the present invention.

FIG. 8 An embodiment of means for correcting an offset between the center of rotation of the stage and the center of the wafer.

FIG. 9 An embodiment of a scan control unit pertaining to an embodiment of the present invention.

FIG. 10 An embodiment of a method for moving the scan position.

### BEST MODE FOR CARRYING OUT THE INVENTION

In the following, the present invention will be described in detail using its exemplary embodiments.

### First Embodiment

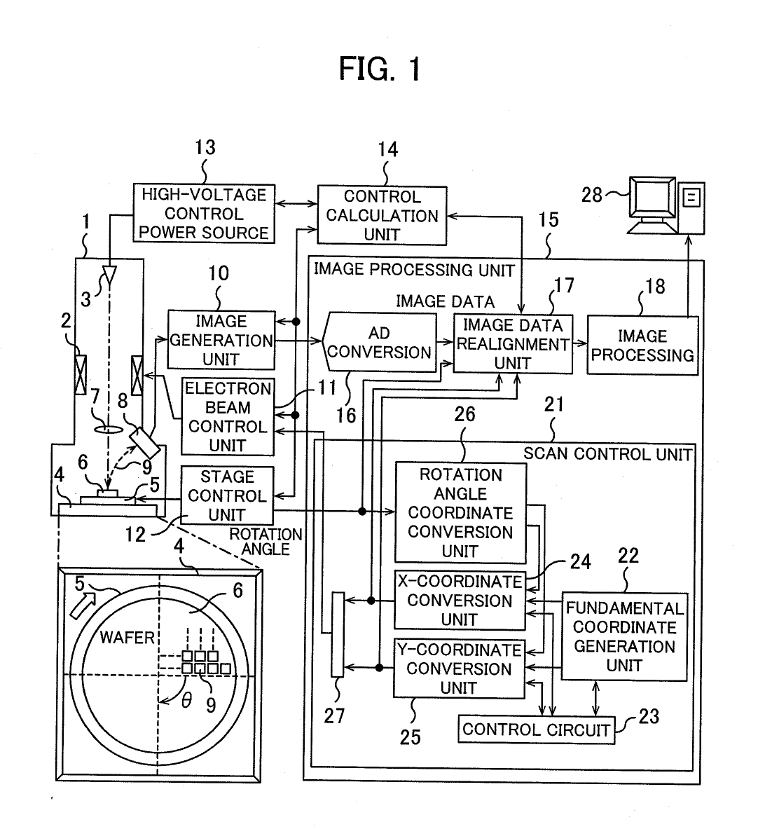

An exemplary embodiment of a pattern testing apparatus for semiconductor wafers pertaining to the present invention is described using the drawings. FIG. 1 illustrates a principle of the present invention. The testing apparatus using an electron beam includes a scanning electron microscope (SEM) 1, a stage 4, an image generation unit 10, an electron beam control unit 11, a stage control unit 12, a high-voltage control power source 13, a control calculation unit 14, an image processing unit 15, and an overall control unit 28.

The image processing unit 15 includes an AD conversion 16, an image data realignment unit 17, an image processor 18, and a scan control unit 21. The scan control unit 21 includes a fundamental coordinate generation unit 22 which generates coordinates representing an electron beam irradiation position, a rotation angle coordinate conversion unit 26 which calculates a correction value of electron beam scan coordinates from stage rotation angle information, an X-coordinate conversion unit 24 and a Y-coordinate conversion unit 25 which perform X-axis coordinate conversion and Y-axis coordinate conversion, respectively, based on correction values depending on an electron beam scan method and correction value information from the rotation angle coordinate conversion unit 26 with respect to coordinates generated by the fundamental coordinate generation unit 22, a control circuit 23 which controls operating timing and data transfer between each component in the scan control unit 21, and an output unit 27 which outputs coordinates information for control of an electron beam scan direction.

The stage 4 includes a stage operating part 5 which makes movements along X-axis and Y-axis and rotational movement and a wafer 6 to be inspected is mounted and held on the stage operating part 5. The scanning electron microscope (SEM) includes an electron gun 3 which emits an electron beam, a scanning coil 2 which controls a position of irradiation of an electron beam emitted from the electron gun 3, an objective lens 7 which controls the beam diameter by controlling the focus of the electron beam, and a secondary electron detector 8 which detects secondary electrons 9 reflected from a specimen as a result of electron beam irradiation. However, the SEM structure is general and schematically depicted here with its essential parts only shown.

In order to detect early or in advance any abnormality and/or any fault involved in the manufacturing process of semiconductor integrated circuits, testing is performed with the use of a testing apparatus at the end of every manufacturing process. A method for testing is to irradiate a specimen by a beam, while beam scanning along a direction of imaging takes place, and acquire image information for a region to be inspected. First, the operation of the scan control unit 21 is described.

Fundamental coordinates for an image size to be acquired are generated by the fundamental coordinate generation unit 22 in the scan control unit 21. For example, if the image size is 512×516, fundamental coordinates are generated as follows: first, X coordinates from 0 to 511 are serially generated with an Y coordinate of 0; likewise, X coordinates from 0 to 511 are then serially generated with an Y coordinate of 1; and this is repeated until corresponding X coordinates have been generated with a Y coordinate of 511. Normally, these fundamental coordinates are used directly as scan coordinates and the scan coordinates are input to the electron beam control unit 11 so that they are scanned by the electron beam.

Here, for scanning in an arbitrary direction, through the use of the X-coordinate conversion unit 24 and the Y-coordinate conversion unit 25, the fundamental coordinates are converted to arbitrary coordinates as the scan coordinates which are input to the electron beam control unit 11 so that they are scanned by the electron beam. In the SEM 1, based on the scan coordinates from the electron beam control unit 11, a specimen such as a semiconductor wafer (e.g., 6 in the figure) is irradiated by the electron beam, secondary electrons 9 reflected from the specimen are detected, and detected signals are output to the image generation unit 10.

In the image generation unit 10, the detected signals are converted to image signals and the image signals are input to the image processing unit 15. In the image processing unit 15, by the AD conversion 16, the input image signals which are analog signals are converted to digital signals which serve as image data. In some configurations, however, analog signals may be A-D converted outside the image processing unit. Image data resulting from the conversion is reordered by the image data realignment unit 17.

Here, when the SEM performed scanning in an arbitrary direction or scanning in accordance with a rotation of the wafer, which will be described later, the obtained image data is reordered into an order suitable for image processing operation by the image processor 18, based on the scan coordinates generated by the scan control unit 21. The image processor 18 executes image processing based on the image data input thereto and sends data to the overall control unit 28. The overall control unit 28 displays image data processed by the image processing and, based on the acquired image information, performs a testing process such as detecting any abnormality and/or any fault involved and measuring the dimensions of process patterns.

By the process as described above, it becomes possible to inspect a wafer while rotating it by implementing scan control and imaging, while rotating the stage operating part 5, and conversion of scan coordinates based on information for a rotation angle of the wafer 6. While an example of testing utilizing electron beam irradiation has been illustrated in the present embodiment, optical laser irradiation can also be implemented with the image processing unit 15 and the stage control unit 12 configured similarly.

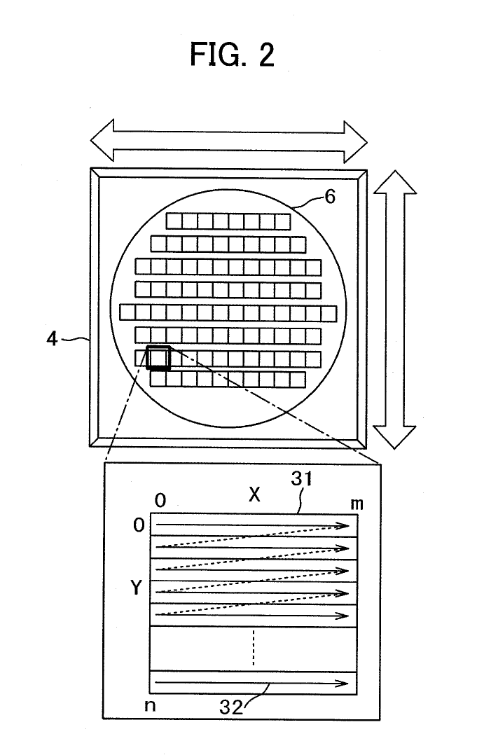

FIG. 2 illustrates an example with regard to a stage and electron beam scanning of related art. The stage of related art moves in a horizontal direction (assumed as an X direction in this example) and a vertical direction (assumed as a Y direction in this example), so that it moves to an electron beam irradiation position on a wafer, that is, a region to be inspected (a die 31 is assumed to be inspected in position in FIG. 2). After moving the stage, electron beam scanning takes place in X-axis and Y-axis directions, as indicated by 32 in the figure, and an image is acquired.

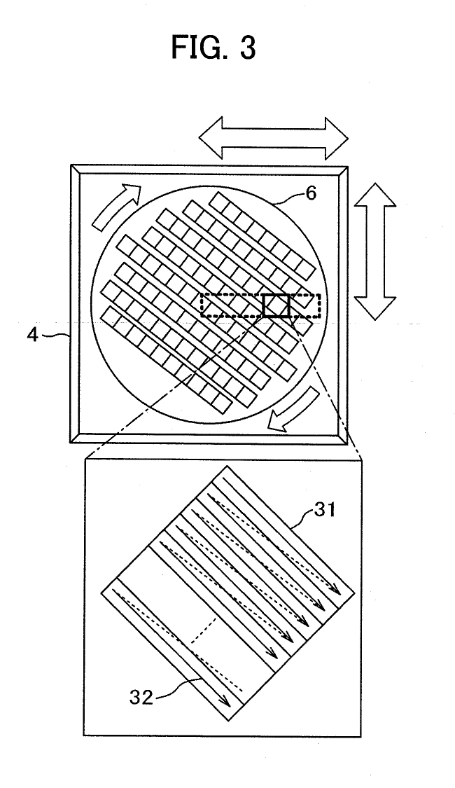

FIG. 3 illustrates stage movement and electron beam scanning operation of the present invention. In the present embodiment, the stage operating range is defined as an area in which it can move from around a center point of a wafer toward one edge of the wafer and anywhere in the whole wafer can be put to testing by providing means for rotating the wafer.

FIG. 3 is an example of scan control to adjust the electron beam scan direction to a rotation angle of the wafer. The stage control unit 12 controls the rotation of the stage 4 and also sends information for a rotation angle relative to the reference angle to the scan control unit 21. Based on this rotation angle information, the scan control unit 21, particularly, the rotation angle coordinate conversion unit 26 generates correction values of X and Y coordinates of scan coordinates. The scan coordinates are corrected by the X-coordinate conversion unit 24 and Y-coordinate conversion unit 25 and output by the output unit 27 to the beam control unit 11 for control of electron beam scanning. In FIG. 3, an arrow direction indicates a scanning direction, the length of an arrow indicates a scanning distance, and spacing between arrows indicates a scanning pitch. This is also true for subsequent figures.

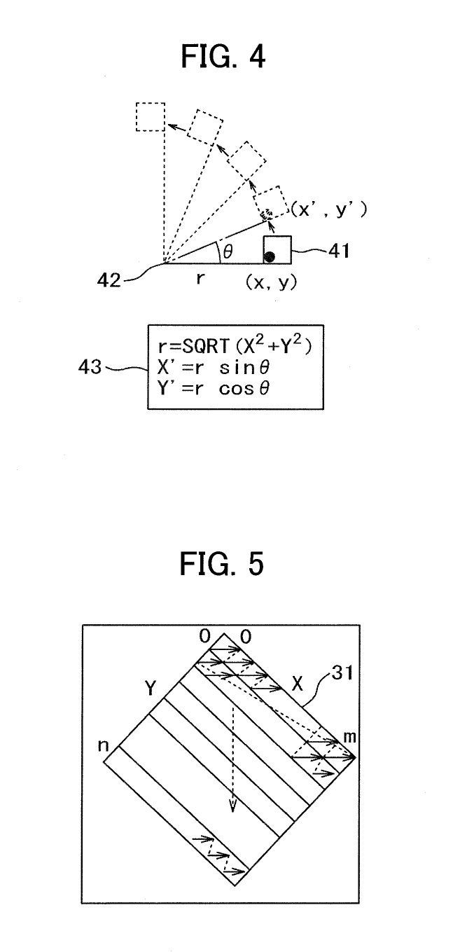

FIG. 4 illustrates an example as to calculating correction values of X and Y coordinates from rotation angle information. If a position (x, y) denoted by 41 in the figure is assumed as the reference coordinates, correction values (x′, Y′) are calculated by an equation denoted by 43 in the figure from a distance r from the reference point 42 and a rotation angle θ.

FIG. 5 illustrates an example of scanning each of pixels of an image that is to be detected along a line direction. That is, in FIG. 5, a die 31 is partitioned into sub-areas (pixels) and each of the pixels is scanned. In the example of FIG. 5, scanning pixel by pixel from (x, y)=(0, 0) moves toward an X coordinate=m. After scanning the X coordinate=m, the scanning moves to the next Y coordinate and goes toward the X coordinate=m. In this scanning method, electron beam deflection can be fined to one direction and deflection control can be simplified.

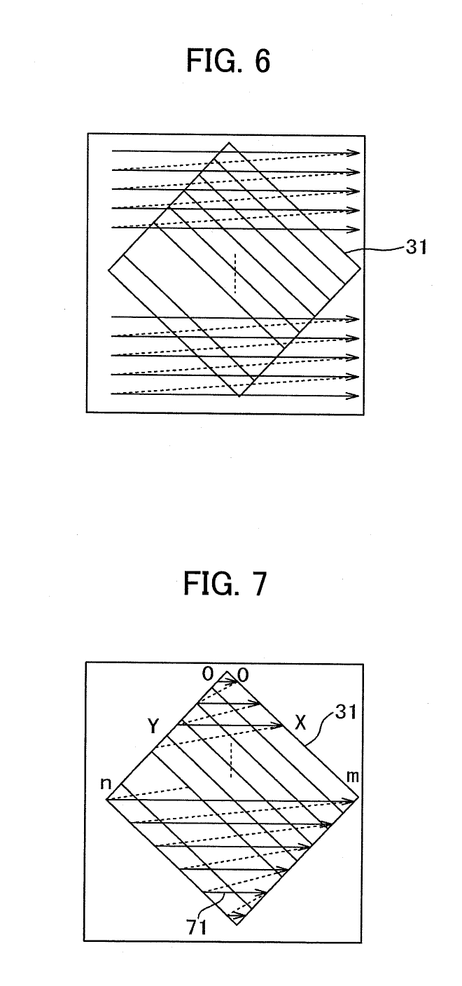

FIG. 6 illustrates an example of electron beam irradiation and scanning with the scanning direction being fixed to one direction (X-axis direction in FIG. 6) regardless of a rotation angle of the wafer. In this case, scanning is performed to cover an area to be inspected 31 and an image is acquired. In an image that is acquired, because the order in which all pixels in the area to be inspected are scanned and imaged changes depending on a rotation angle, a two-dimensional image of the area is reconstructed. In FIG. 6, the scanning distance is larger than the length of one side of the die 31 and equal to a diagonal dimension of the die 31.

From the acquired image, the coordinates within the area to be inspected are corrected by the image data realignment unit 17, based on a rotation angle of the area to be inspected, relative to the reference coordinates. Base on the result of this, only the area to be inspected is extracted from the acquired image. The coordinate calculation based on a rotation angle is the same as the embodiment shown in FIG. 4. In the scanning method as illustrated in FIG. 6, the scanning direction can be fixed to one direction regardless of a rotation angle and scan control can be simplified. Because stage control and scan control do not need to be performed concurrently, time for coordinate conversion from rotation angle information is not included in the testing throughput and thus the testing speed can be improved.

FIG. 7 illustrates an example in which the scanning as illustrated in FIG. 6 is limited to only the area to be inspected 31. The area to be inspected 31 shown in FIG. 7 corresponds to a die. Limiting the scanning to the area is achieved by obtaining coordinates in the area to be inspected based on coordinate correction values calculated as in the embodiment shown in FIG. 4 and controlling the scan area. In the example of FIG. 7, the scanning can be limited to the area to be inspected and the scan time can be shortened. As compared with FIG. 6, it is possible to dispense with the step of removing data for the area to be inspected after the scanning.

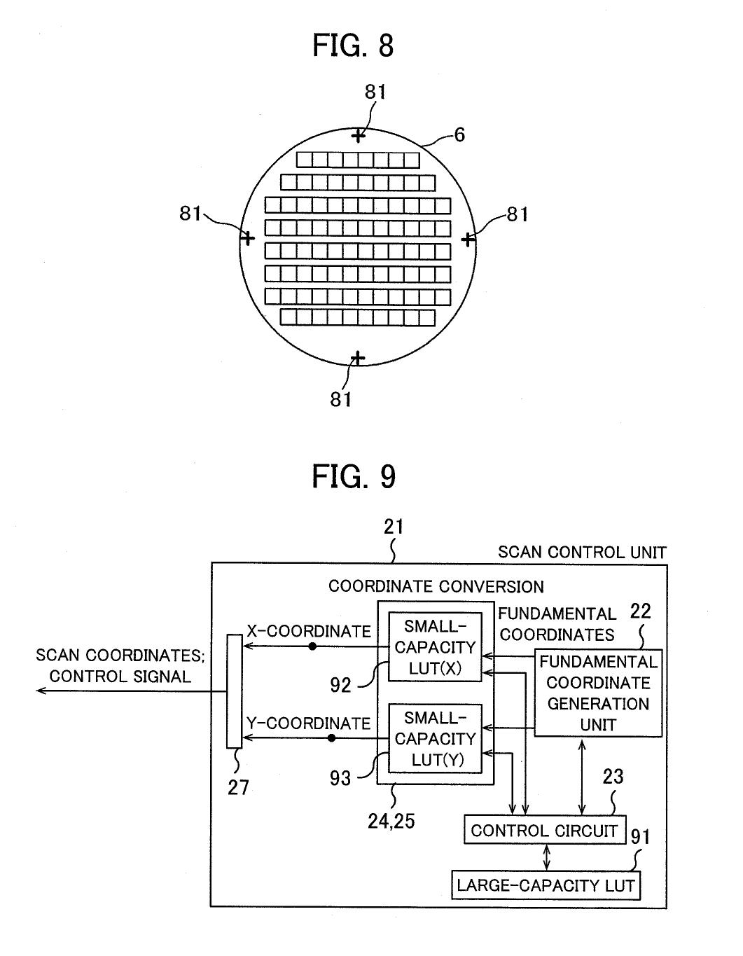

FIG. 8 illustrates a method for correcting an offset of the center of rotation. When a wafer is mounted on the stage, there may be an offset between the center of rotation of the stage and the center of the wafer due to a mechanical precision limitation of a transport system. As means for detecting this offset, positioning marks 81 are provided in plurality of places on a wafer.

In the example of FIG. 8, the example is shown in which the marks are provided in four places on the rim of the wafer. These marks are provided in positions equidistant from the center point of the wafer. As the stage is rotated, the imaged marks are input and positional offsets are compared, according to a typical pattern image acquisition method. If there is an alignment between the center of rotation of the stage and the center of the wafer, the marks are arranged on the circumstance of the same circle. When the same position is irradiated by the electron beam and an image is input, the same mark image is detected.

However, if there is a center point offset, the mark images do not match, and the offset can thus be detected. In the example of FIG. 8, an offset direction of the center point can be detected by the offset direction of the intersection points of the detected mark images. Based on the thus detected offset, positional correction depending on the offset is made for the image for testing by the image data realignment unit 17 and the image processor 18. In another embodiment, information for the detected offset is sent to the stage control unit 12 and it is also possible to make alignment between the center of rotation of the stage and the center of the wafer by moving the stage in X and Y directions.

FIG. 8 shows an example in which the marks are formed in the perimeter of the wafer, separately from the die. However, instead of forming the marks in the perimeter of the wafer separately, it is also possible to select and mark a given position in a die. In this case, by selecting given corresponding positions in a plurality of dies, it is possible to achieve the same effect as described with reference to FIG. 8.

FIG. 9 illustrates an embodiment of implementing coordinate conversion in the scan control unit. The figure depicts a configuration in which the X-coordinate conversion unit 24 and the Y-coordinate conversion unit 25 make use of small-capacity conversion tables (LUT) for high-speed conversion of X and Y scan coordinates and a large-capacity conversion table (LUT) with a capacity for a plurality of image sizes, storing scan type specific conversion data to handle a plurality of scan types.

X-coordinate and Y-coordinate conversion is performed by storing mapping data for conversion in advance in the conversion tables (LUTs). The conversion tables are memories and conversion data is stored in the memories. A pair of fundamental coordinates generated by the fundamental coordinate generation unit 22 specifies an address. By reading data stored at the address, coordinate conversion is performed.

Here, the capacity of a small-capacity conversion table is equivalent to an image size. If, for example, one pixel is represented by 16-bit digital data in an image size of 512×512, the capacity will be 16 bits×512=8192 bits. Since this is provided for X coordinate and Y coordinate respectively, there are two conversion tables with the capacity of 8192 bits. Owing to the fact that the small-capacity conversion table (LUT) has a minimum memory capacity corresponding to an image size, high-speed operation is feasible.

In the large-capacity conversion table (LUT) 91, scan type specific conversion data is stored to handle a plurality of scan types. During a scan operation, high-speed coordinate conversion is performed using the small-capacity conversion tables 92, 93. During a pause of scan, conversion data is transferred from the large-capacity conversion table (LUT) 91 to the small-capacity conversion tables 92, 93. Thereby, a large variety of scan coordinates can be generated depending on a rotation angle with fewer hardware resources.

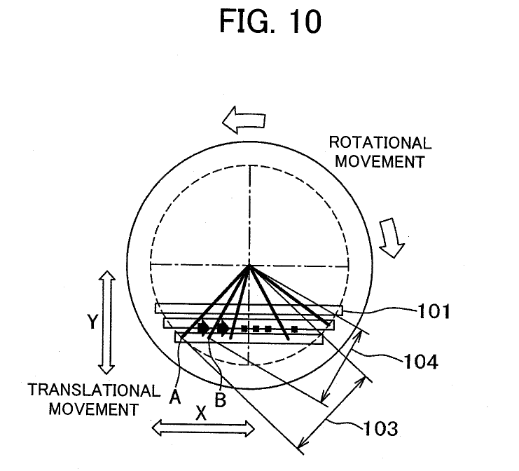

FIG. 10 illustrates an embodiment of a method for positioning the electron beam irradiation position by stage movement. To implement the same image acquisition as with testing using the X-Y stage of related art, moving the irradiation position suitably for a die arrangement on a wafer can be implemented by combination of stage rotation and movement in X and Y directions over a distance corresponding to the radius of the rotation in the present invention. After determining an arbitrary origin position and determining displacements in X and Y directions from a required angle of movement and a distance from the center, movement to a position to be inspected takes place in combination with rotation.

In FIG. 10, reference numeral 101 denotes a region where dies are arranged in horizontal strips. After acquiring data for an area indicated by A, it is possible to acquire data for an area B located in the same horizontal strip by rotating the wafer by a given angle and then moving the stage in X and Y directions as well. The given angle may be one full rotation (360 degrees). In FIG. 10, reference numeral 103 denotes the radius of the rotation, when acquiring the data for the area A, and reference numeral 104 denotes the radius of the rotation, when acquiring the data for the area B.

According to the method as in FIG. 10, data for dies arranged in a horizontal strip can be acquired sequentially from the left, like data acquisition by way of the X-Y stage of related art, and a data processing method of related art can be used.

As described hereinbefore, according to the present invention, it is possible to reduce the size and the weight of the stage that holds a wafer and moves it to an irradiation region. It is also possible to improve the testing throughput by precluding a decrease in the throughput due to an acceleration limit (a high torque limit of the motor) attributed to increased weight of the stage of related art. Such stage involves an inversion movement that is now eliminated by the present invention. Thus, the present invention makes it possible to reduce the vibration of the stage support platform and improve the resolution and precision of the testing.

### EXPLANATION OF REFERENCE NUMERALS

1 Scanning electron microscope (SEM)
2 Scanning coil
3 Electron gun that emits an electro beam
4 Stage
5 Stage operating part
6 Wafer
7 Objective lens
8 Secondary electron detector
9 Secondary electrons
10 Image generation unit
11 Electron beam control unit
12 Stage control unit
13 High-voltage control power source
14 Control calculation unit
15 Image processing unit
16 AD conversion
17 Image data realignment unit
18 Image processor
20 Reordering memory
21 Scan control unit
22 Fundamental coordinate generation unit
23 Control circuit
24 X-coordinate conversion unit
25 Y-coordinate conversion unit
26 Rotation angle coordinate conversion unit
27 Output unit

1. A semiconductor wafer testing apparatus that irradiates a wafer by an electron beam and acquires image information, the semiconductor wafer testing apparatus comprising:
means for rotating the wafer around the center of the wafer; means for irradiating a surface of the wafer that is rotating by the electron beam; means for detecting secondary electrons that are generated from the wafer; and means for acquiring image information based on signals obtained by detecting the secondary electrons.

2. A semiconductor wafer testing apparatus that irradiates and scans a wafer by an electron beam and acquires image information for a region to be inspected through the use of a scanning electron microscope that irradiates a wafer by an electron beam, detects secondary electrons emitted from the wafer, converts signals obtained by detecting the secondary electrons into image signals, displays an image on a screen, and observes the wafer, the semiconductor wafer testing apparatus comprising:
means for rotating the wafer around the center of the wafer; an electronic optical system that scans a surface of the wafer that is rotating on the stage by the electron beam; a detector that detects secondary electrons that are generated from the wafer by the electron beam, and display means that reorders the signals based on the detected secondary electrons and displays an image.

3. A semiconductor wafer testing apparatus that irradiates a wafer by an electron beam and acquires image information, the semiconductor wafer testing apparatus being provided with:
means for rotating the wafer around the center of the wafer; and means for irradiating the wafer, the surface of which is rotating, by an electron beam;
means for detecting secondary electrons that are generated from the wafer by the irradiating means;
means for obtaining a rotation angle of the wafer; means for controlling a direction and a distance of electron beam scanning based on information for the rotation angle; and means for acquiring image information based on signals obtained by detecting the secondary electrons.

4. A semiconductor wafer testing apparatus that irradiates a wafer by an electron beam and acquires image information, the semiconductor wafer testing apparatus being provided with:
means for rotating the wafer around the center of the wafer; and means for irradiating the wafer, the surface of which is rotating, by an electron beam;
means for detecting secondary electrons that are generated from the wafer by the irradiating means;
means for controlling scanning with the electron beam; means for obtaining a rotation angle of the wafer; means for reordering acquired images according to information for the rotation angle; and means for acquiring image information based on signals obtained by detecting the secondary electrons.

5. A semiconductor wafer testing apparatus that irradiates a wafer in which a plurality of quadrilateral dies are formed by an electron beam and acquires image information, the semiconductor wafer testing apparatus being provided with:
means for rotating the wafer around the center of the wafer; means for irradiating the surface of the wafer that is rotating by an electron beam; means for detecting secondary electrons that are generated from the wafer; means for controlling scanning with the electron beam; and means for obtaining a rotation angle of the wafer;
means for scanning over a given distance, at a given pitch, and in the same direction, covering one of the quadrilateral dies based on information for the rotation angle;
means for reordering acquired images according to information for the rotation angle; and means for acquiring image information based on signals obtained by detecting the secondary electrons.

6. The semiconductor wafer testing apparatus according to claim 5, wherein the given distance of the scanning is larger than a length of one side of the each die.

7. The semiconductor wafer testing apparatus according to claim 5, wherein the given distance of the scanning is equal to a diagonal dimension of the each die.

8. The semiconductor wafer testing apparatus according to claim 1, being provided with means for calculating an area to be inspected from the obtained rotation angle information and means for controlling the direction and the distance of scanning based on a result of calculation by the calculating means.

9. The semiconductor wafer testing apparatus according to claim 8, wherein the area to be inspected is identical to the each die.

10. The semiconductor wafer testing apparatus according to claim 1, being provided with means for arranging a plurality of positioning marks on the same circle in a perimeter of the wafer and recognizing the marks, means for calculating an offset of the center of the wafer from position offsets of the marks recognized, and means for correcting a scanning position based on the calculated offset.

11. The semiconductor wafer testing apparatus according to claim 1, being provided with means for arranging a plurality of positioning marks on the same circle in the perimeter of the wafer and recognizing the marks, means for calculating an offset of the center of the wafer from the position offsets of the marks recognized, and means for correcting the acquired image information based on the calculated offset of the center.

12. The semiconductor wafer testing apparatus according to 1, being provided with means for acquiring image information for a plurality of circuit pattern images, means for calculating an offset of the center of the wafer based on the image information, and means for correcting the acquired image information based on the calculated offset of the center.
